(19) United States
(12) Patent Application Publication
(10) Pub. No.: US 2020/0350909 A1
(43) Pub. Date: Nov. 5, 2020

(54) SEMICONDUCTOR DEVICE

(71) Applicant: NEC Corporation, Minato-ku, Toky (JP)

(72) Inventors: Makoto MIYAMURA, Tokyo (JP); Ryusuke NEBASHI, Tokyo (JP); Toshitsugu SAKAMOTO, Tokyo (JP); Yukihide TSUJI, Tokyo (JP); Xu BAI, Tokyo (JP); Ayuka TADA, Tokyo (JP)

(73) Assignee: NEC Corporation, Minato-ku, Tokyo (JP)

(21) Appl. No.: 16/964,392

(22) PCT Filed: Feb. 8, 2019
(86) PCT No.: PCT/JP2019/004663

§ 371 Date: Jul. 23, 2020

(30) Foreign Application Priority Data
Feb. 14, 2018 (JP) 2018-023845

(51) Int. Cl. H03K 17/693; G11C 13/00

(52) U.S. Cl. CPC H03K 17/693; G11C 13/0069; G11C 13/0097; G11C 13/0038; G11C 13/004

(57) ABSTRACT

A semiconductor device includes: first wires which extend in a first direction; second wires extending in a second direction; a unit element which comprises two variable resistance elements connected in series, and has one end connected to a first wire and the other end connected to a second wire; a first control line for controlling the supply of a voltage to the first wire; a second control line for controlling the supply of a voltage to the second wire; and a cell circuit connected to an intermediate node between the two variable resistance elements and also connected to the first control line and the second control line. The cell circuit has: a cell transistor connected to an intermediate node writing driver which supplies a voltage to the intermediate node; and a cell control circuit which controls an electrical conduction state of the cell transistor.

### TECHNICAL FIELD

The present invention relates to a semiconductor device using a resistance change nonvolatile element.

### BACKGROUND ART

An integration density of a field-effect transistor has been significantly increasing with a higher-density semiconductor integrated circuit, and a photomask and a design verification cost being needed for manufacturing an integrated circuit have been increasing. As a result, a development cost of an application specific integrated circuit (ASIC) in which a customized fixed function is previously designed by a user has also been increasing sharply. Under such a situation, a field programmable gate array (FPGA) in which a designer can electrically program a desired circuit for a manufactured semiconductor chip has been receiving attention.

In general, the FPGA requires more transistors by equal to or more than one digit in order to exhibit the same function as the ASIC, has a smaller area efficiency, and has more power consumption than those of the ASIC. Thus, power saving and low power are required by reducing an overhead of the FPGA. One of solutions to the above-mentioned problem is to achieve programmable wiring equipped with a resistance change nonvolatile element (also referred to as a resistance change element) inside a multilayer wiring layer. Examples of such a resistance change element include a resistance random access memory (ReRAM) using a transition-metal oxide, NanoBridge (registered trademark) using an ion conductor, and the like.

PTL 1 discloses a semiconductor device including a unit element that includes a first switch and a second switch including a resistance change layer of a resistance change type of which resistance state changes according to a polarity of an applied voltage. Each of the first switch and the second switch includes two electrodes. One of the electrodes of the first switch and one of the electrodes of the second switch are connected to each other and form a common node. The other electrode of the first switch forms a first node, and the other electrode of the second switch forms a second node. Further, the semiconductor device in PTL 1 includes a crossbar constituted of a first wire and a second wire being connected to each other via the unit element.

PTL 2 discloses a semiconductor device including a first switch and a second switch of a resistance change type of which resistance state changes by satisfying a predetermined condition after energization. The semiconductor device in PTL 2 includes a first wire and a second wire that constitute a crossbar, a first selection switch connected to the first wire, and a second selection switch element connected to the second wire. The first switch includes a first terminal to be connected to the first wire, and a second terminal. The second switch includes a third terminal that is connected to the second terminal of the first switch and forms an intermediate node, and a fourth terminal to be connected to the second wire.

In the semiconductor devices in PTLs 1 and 2, an intersection point of the crossbar can be uniquely selected by providing an appropriate decoding signal to a selection transistor. The semiconductor devices in PTLs 1 and 2 can improve a writing margin with respect to an OFF disturbance that is written by mistake to a resistance change element in a high resistance state by a logic amplitude of a signal.

### CITATION LIST

### Patent Literature

[PTL 1] International Publication No. WO2012/043502

[PTL 2] International Publication No. WO2013/190741

### SUMMARY OF INVENTION

### Technical Problem

In the semiconductor devices in PTLs 1 and 2, a unit element including two resistance change elements formed in pair having a bipolar writing characteristic is disposed at an intersection point of a crossbar circuit. A voltage of a different polarity is applied to the resistance change element of the crossbar circuit in PTLs 1 and 2 during writing and erasing. Thus, a voltage drop due to a transistor to be disposed between a writing driver and the resistance change element may be different during writing or erasing. In this case, a voltage applied to the resistance change element during either writing or erasing may be insufficient for changing a resistance state of the resistance change element.

Further, in the semiconductor devices in PTLs 1 and 2, a voltage that can be applied to the resistance change element during writing or erasing can be increased by increasing a writing voltage to be supplied from the writing driver and a voltage of a decoding signal to be supplied from an external circuit. However, since the transistor is limited in terms of pressure resistance, an increase in set voltage may become a factor in reducing a writing margin with respect to an OFF disturbance. Further, there is also a problem that a size of the whole circuit increases when a large transistor is used in order to improve pressure resistance of the transistor.

In order to solve the above-mentioned problem, an object of the present invention is to provide a semiconductor device capable of suppressing a decrease in applied voltage to a resistance change element during writing and erasing, in a crossbar circuit using the resistance change element.

### Solution to Problem

A semiconductor device according to one aspect of the present invention includes: a plurality of first wires extending in a first direction; a plurality of second wires extending in a second direction; a unit element that includes two resistance change elements connected in series, has one end connected to the first wire, and has another end connected to the second wire; a first control line for controlling a voltage supply to the first wire; a second control line for controlling a voltage supply to the second wire; and a cell circuit to be connected to an intermediate node of the two resistance change elements, and also to be connected to the first control line and the second control line, and the cell circuit includes a cell transistor to be connected to an intermediate node writing driver that supplies a voltage to the intermediate node, and a cell control circuit that controls a continuity state of the cell transistor.

### Advantageous Effects of Invention

The present invention is able to provide a semiconductor device capable of suppressing a decrease in applied voltage to a resistance change element during writing and erasing in a crossbar circuit using the resistance change element.

### BRIEF DESCRIPTION OF DRAWINGS

FIG. 1 is a schematic diagram illustrating one example of a circuit configuration of a crossbar circuit according to a first example embodiment of the present invention.

FIG. 2 is a flowchart illustrating one example of a programming method of the crossbar circuit according to the first example embodiment of the present invention.

FIG. 3 is a schematic diagram illustrating one example of a circuit configuration of a crossbar circuit according to a related art.

FIG. 4 is a schematic diagram illustrating one example of a current path when writing and erasing of a selection target unit element is performed in the crossbar circuit according to the related art.

FIG. 5A is a schematic diagram illustrating one example of a circuit to be formed when writing is performed in the unit element to be selected in the crossbar circuit according to the related art.

FIG. 5B is a schematic diagram illustrating one example of a circuit to be formed when erasing is performed in the unit element to be selected in the crossbar circuit according to the related art.

FIG. 6 is a schematic diagram illustrating one example of a current path when writing and erasing of a unit element to be selected is performed in the crossbar circuit according to the first example embodiment of the present invention.

FIG. 7A is a schematic diagram illustrating one example of a circuit to be formed when writing is performed in the unit element to be selected in the crossbar circuit according to the first example embodiment of the present invention.

FIG. 7B is a schematic diagram illustrating one example of a circuit to be formed when erasing is performed in the unit element to be selected in the crossbar circuit according to the first example embodiment of the present invention.

FIG. 8 is a schematic diagram illustrating one example of a circuit configuration of a crossbar circuit according to a second example embodiment of the present invention.

FIG. 9 is a schematic diagram illustrating one example of a circuit configuration of a crossbar circuit according to a third example embodiment of the present invention.

FIG. 10 is a schematic diagram illustrating one example of a circuit configuration of a crossbar circuit according to a fourth example embodiment of the present invention.

FIG. 11 is a schematic diagram illustrating one example of a circuit configuration of a crossbar circuit according to a fifth example embodiment of the present invention.

FIG. 12 is a block diagram illustrating one example of a configuration of a semiconductor device according to a sixth example embodiment of the present invention.

FIG. 13 is a schematic diagram illustrating one example of a circuit configuration for simulating the crossbar circuit according to the first example embodiment of the present invention.

FIG. 14 is a schematic diagram illustrating one example of a circuit configuration for simulating the crossbar circuit according to the related art.

FIG. 15 is a schematic diagram illustrating one example of simulation results of the crossbar circuits according to the first example embodiment of the present invention and the related art.

FIG. 16 is a schematic diagram illustrating another example of simulation results of the crossbar circuits according to the first example embodiment of the present invention and the related art.

FIG. 17 is a schematic diagram illustrating one example of a circuit configuration for simulating the crossbar circuit according to the second example embodiment of the present invention.

FIG. 18 is a schematic diagram illustrating one example of simulation results of the crossbar circuits according to the second example embodiment of the present invention and the related art.

### EXAMPLE EMBODIMENT

Hereinafter, example embodiments of the present invention will be described by using drawings. However, limitation technically preferable to implement the present invention is imposed on the example embodiments described below, but the example embodiments do not limit the scope of the invention to the following description. Further, in all the drawings used for the description of the example embodiments below, a similar configuration is provided with the same reference sign and the reference sign is omitted unless there is a particular reason. Further, in all the drawings used for the description of the example embodiments below, a symbol such as a number and a letter of the alphabet may be provided after a reference sign in order to distinguish between different individuals having a similar configuration. Further, in the description of the example embodiments below, a number after a reference sign may be omitted when different individuals are not distinguished in relation to a similar configuration. Further, repetitive description of similar configuration and operation may be omitted in the example embodiments below.

### First Example Embodiment

First, a crossbar circuit (also referred to as a semiconductor device) according to a first example embodiment of the present invention will be described with reference to the drawings. According to the present example embodiment, an example in which a transistor mounted on the crossbar circuit is constituted of a metal-oxide-semiconductor field-effect transistor (nMOSFET) will be described.

### (Configuration)

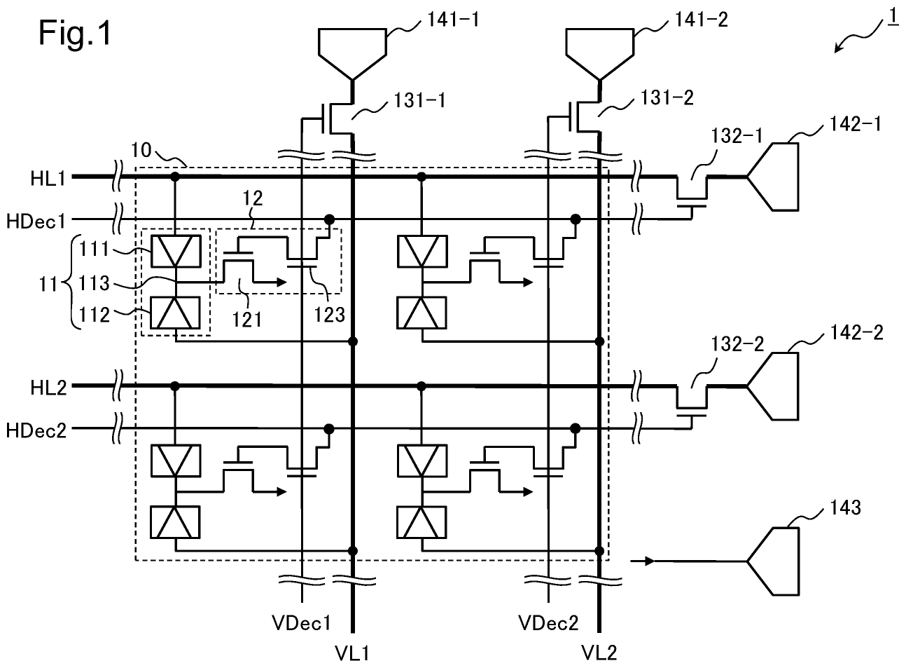

FIG. 1 is a schematic diagram illustrating one example of a configuration of a crossbar circuit 1 according to the present example embodiment. As in FIG. 1, the crossbar circuit 1 includes a wiring network 10, a unit element 11, and a cell circuit 12. The wiring network 10 includes a first wire VL, a second wire HL, a first decoding line VDec, and a second decoding line HDec. The unit element 11 includes a first resistance change element 111 and a second resistance change element 112. The cell circuit 12 includes a cell transistor 121 and a cell control transistor 123. Note that, according to the present example embodiment, two groups of the first wires VL, the second wires HL, the first decoding lines VDec, and the second decoding lines HDec are illustrated, but no limitation is imposed on the number thereof. Similarly, according to the present example embodiment, four groups of the unit elements 11 and the cell circuits 12 are illustrated, but no limitation is imposed on the number thereof.

The first wire VL extends in a column direction (also referred to as a first direction) and is connected to a first writing driver 141 via a first selection transistor 131. The second wire HL extends in a row direction (also referred to as a second direction) and is connected to a second writing driver 142 via a second selection transistor 132. The cell circuit 12 is connected to an intermediate node writing driver 143. Note that the first selection transistor 131 and the second selection transistor 132 may be included in the configuration of the crossbar circuit 1. Further, the first writing driver 141, the second writing driver 142, and the intermediate node writing driver 143 may be included in the configuration of the crossbar circuit 1.

For example, a transistor such as the cell transistor 121, the cell control transistor 123, the first selection transistor 131, and the second selection transistor 132 can be constituted of the nMOSFET. Further, a transistor to be mounted on the crossbar circuit 1 may be constituted of a pMOSFET. A unified polarity is preferable to the transistor to be mounted on the crossbar circuit 1.

The wiring network 10 is broadly divided into a crossbar and a decoding wiring network. The crossbar is constituted of the plurality of first wires VL and second wires HL. The decoding wiring network is constituted of the plurality of first decoding lines VDec (also referred to as first control lines) and second decoding lines HDec (also referred to as second control lines).

The unit element 11 is disposed at a place where the first wire VL and the second wire HL constituting the crossbar intersect each other. In other words, the first wire VL and the second wire HL are connected to each other via the unit element 11 at a place where the first wire VL and the second wire HL intersect each other.

The first decoding line VDec and the second decoding line HDec constituting the decoding wiring network are a signal line for performing writing control on any unit element 11. For example, the first decoding line VDec is installed along the first wire VL. For example, the second decoding line HDec is installed along the second wire HL. The decoding wiring network is connected to a control device and a host system that are not illustrated.

The first decoding line VDec is connected to a gate of the first selection transistor 131. Further, the first decoding line VDec is commonly connected to a gate of the cell control transistor 123 associated with the unit element 11 that belongs to the same column of the crossbar. The second decoding line HDec is connected to a gate of the second selection transistor 132. Further, the second decoding line HDec is commonly connected to a diffusion layer of the cell control transistor 123 associated with the unit element 11 that belongs to the same row of the crossbar. In other words, the first decoding line VDec and the second decoding line HDec are respectively connected to the first selection transistor 131 and the second selection transistor 132, and also extend and are included inside the crossbar. A continuity state (ON/OFF) of the first selection transistor 131 and the second selection transistor 132 is controlled via the first decoding line VDec and the second decoding line HDec.

The unit element 11 is disposed at an intersection point of the crossbar. The unit element 11 includes the first resistance change element 111 and the second resistance change element 112. The first resistance change element 111 and the second resistance change element 112 have a structure in which a resistance change layer of which resistance state changes according to a polarity of an applied voltage is sandwiched between a pair of electrodes. For example, the first resistance change element 111 and the second resistance change element 112 that constitute the unit element 11 can be configured to have a combination of bipolar type switches having reversed polarities. The bipolar type switch refers to a resistance change element of which resistance value changes according to a polarity of an applied voltage or current. Note that no limitation is imposed on a combination of the first resistance change element 111 and the second resistance change element 112 that constitute the unit element 11. Further, in the following, when the first resistance change element 111 and the second resistance change element 112 are not distinguished, they are described as a resistance change element without distinction.

Each of the first resistance change element 111 and the second resistance change element 112 includes two terminals facing each other across a resistance change layer. One of the terminals of the first resistance change element 111 is connected to the second wire HL. One of the terminals of the second resistance change element 112 is connected to the first wire VL. The other terminals of the first resistance change element 111 and the second resistance change element 112 are connected to each other and form an intermediate node 113, and are connected to one side of diffusion layer of the cell transistor 121. The intermediate node 113 is connected to the intermediate node writing driver 143 via the cell transistor 121.

The cell circuit 12 is disposed in such a way as to be associated with the unit element 11 to be disposed in each position where the first wire VL and the second wire HL constituting the crossbar intersect each other. The cell circuit 12 is constituted of the cell transistor 121 and the cell control transistor 123.

One of the diffusion layers of the cell transistor 121 is connected to the intermediate node 113 of the unit element 11. The other diffusion layer of the cell transistor 121 is connected to the intermediate node writing driver 143. A gate of the cell transistor 121 is connected to one of the diffusion layers of the cell control transistor 123. In FIG. 1, a connection between the cell transistor 121 and the intermediate node writing driver 143 is indicated by an arrow.

One of the diffusion layers of the cell control transistor 123 is connected to the gate of the cell transistor 121. The other diffusion layer of the cell control transistor 123 is connected to the second decoding line HDec common to the other cell control transistor 123 that constitutes the same row of the crossbar. The gate of the cell control transistor 123 is connected to the first decoding line VDec common to the other cell control transistor 123 that constitutes the same column of the crossbar.

The first writing driver 141 is connected to the first wire VL via a diffusion layer of the first selection transistor 131. Further, the first decoding line VDec is connected to the gate of the first selection transistor 131. The second writing driver 142 is connected to the second wire HL via a diffusion layer of the second selection transistor 132. Further, the second decoding line HDec is connected to the gate of the second selection transistor 132. For example, the first writing driver 141 and the second writing driver 142 are driven and controlled by the control device and the host system that are not illustrated. Further, for example, a continuity state of the first selection transistor 131 and the second selection transistor 132 is controlled by the control device and the host system that are not illustrated.

A continuity state of the cell transistor 121 is switched depending on a continuity state of the cell control transistor 123. The continuity state of the cell control transistor 123 is an ON state when the first decoding line VDec is at a selection level (High), and is an OFF state when the first decoding line VDec is at a non-selection level (Low).

The cell transistor 121 is in an ON state when the first decoding line VDec is at the selection level (High) and the second decoding line HDec is at the selection level (High). At this time, the intermediate node 113 and the intermediate node writing driver 143 are connected to each other via the cell transistor 121. By controlling a polarity of a voltage or a current between either the first writing driver 141 or the second writing driver 142 and the intermediate node writing driver 143 in this state, the resistance change element included in the unit element 11 to be selected can be programmed. For example, a polarity of a voltage or a current between either the first writing driver 141 or the second writing driver 142 and the intermediate node writing driver 143 is controlled by the control device that is not illustrated.

### <Programming Method>

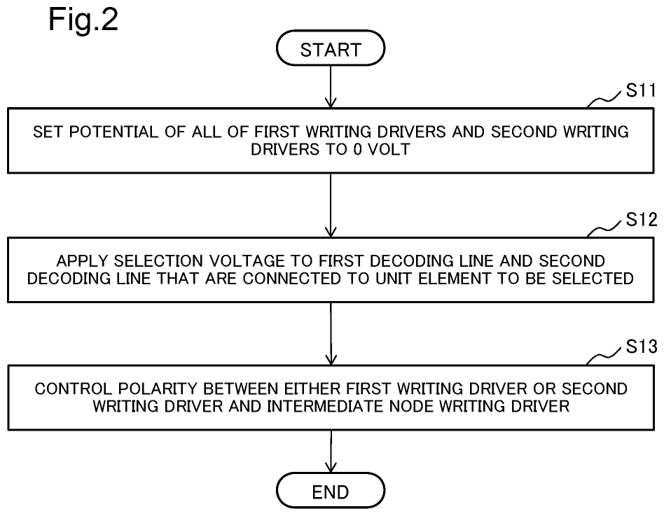

Next, one example of a programming method (also referred to as a writing method) of the unit element 11 included in the crossbar circuit 1 will be described with reference to the drawing. FIG. 2 is a flowchart illustrating one example of the programming method of the crossbar circuit 1. Note that the following programming method is one example, and does not limit the programming method of the crossbar circuit 1 according to the present example embodiment. Further, description is given below on the assumption that the control device that is not illustrated performs programming control.

In FIG. 2, first, the control device sets all of the first writing drivers 141 and the second writing drivers 142 to 0 volt (step S11).

Next, the control device sets, to a selection level (High), the first decoding line VDec and the second decoding line HDec associated with the unit element 11 to be selected, and connects the intermediate node 113 and the intermediate node writing driver 143 (step S12). At this time, the control device sets, to a non-selection level (Low), the first selection transistor 131 and the second selection transistor 132 associated with the unit element 11 to be non-selected. As a result, the unit element 11 to be selected is in an ON state, and the unit element 11 to be non-selected is in an OFF state. For example, when only the unit element 11 on the upper left is brought into an ON state in FIG. 1, a first selection transistor 131-1 to be connected to a first decoding line VDec1 and a second selection transistor 132-2 to be connected to a second decoding line HDec2 are brought into a continuity state.

Next, the control device controls a polarity of a voltage or a current between either the first writing driver 141 or the second writing driver 142 and the intermediate node writing driver 143 while the selected unit element 11 is in a ON state, and performs writing (step S13).

The description above is description of one example of the programming method of the unit element 11 according to the flowchart in FIG. 2.

In the crossbar circuit 1, when a voltage of a source terminal of the cell control transistor 123 is at the selection level (High) and a voltage of a gate terminal is at the non-selection level (Low), a subthreshold leak may occur. When the subthreshold leak occurs, a gate electrode of the cell transistor 121 is charged and brought into a semi-selection state. In order to prevent the gate electrode of the cell transistor 121 from being brought into a semi-selection state, the second decoding line HDec connected to the diffusion layer of the cell control transistor 123 may be precharged to 0 volt before writing. Then, writing may be terminated before the cell transistor 121 is brought into a semi-selection state. Note that, when a writing time is insufficient, the above-described procedure may be repeated for a plurality of times.

### <Related Art>

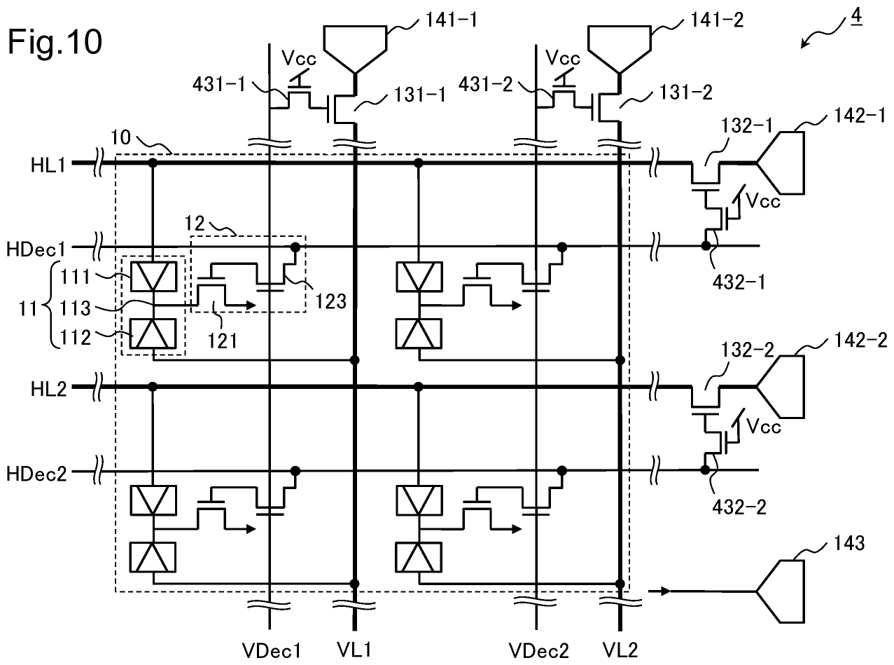

Herein, a crossbar circuit according to a related art (FIG. 10 and the like in International Publication No. WO2013/190741) will be described in order to describe an advantageous effect of the crossbar circuit 1 according to the present example embodiment. The crossbar circuit according to the related art is different from the crossbar circuit 1 according to the present example embodiment in a configuration of a cell circuit. Note that, with regard to the related art, a configuration similar to that of the present example embodiment has the same reference sign, and detailed description thereof is omitted.

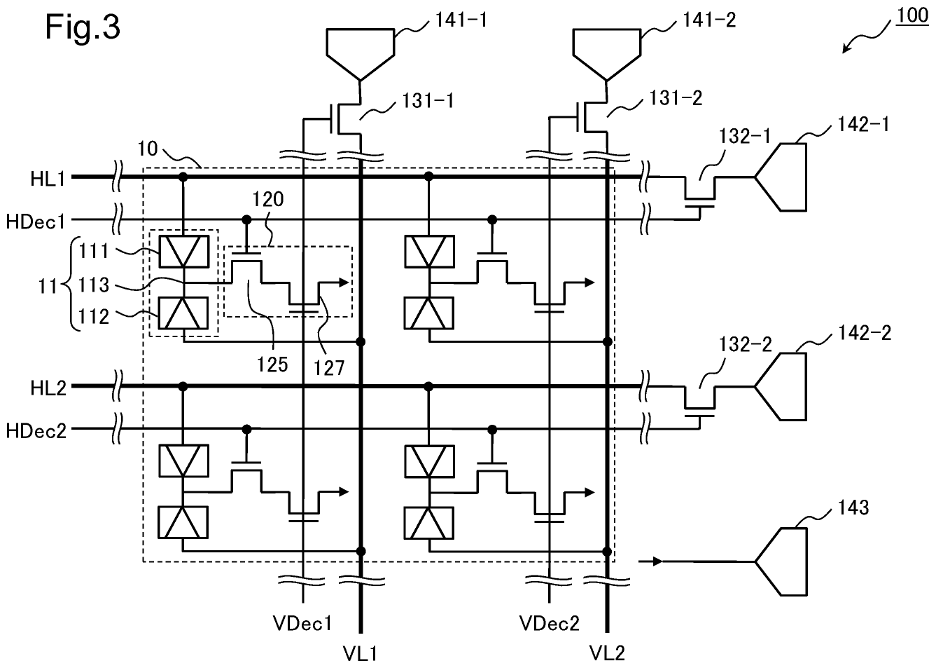

FIG. 3 is a schematic diagram illustrating a configuration of a crossbar circuit 100 according to the related art. The crossbar circuit 100 according to the related art includes a wiring network 10, a unit element 11, and a cell circuit 120. Since the wiring network 10 and the unit element 11 are similar except for a connection state with the cell circuit 120, detailed description thereof will be omitted.

The cell circuit 120 is disposed in such a way as to be associated with the unit element 11 to be disposed in a position where a first wire VL and a second wire HL constituting a crossbar intersect each other. The cell circuit 120 includes a first cell transistor 125 and a second cell transistor 127. The cell circuit 120 is different from the cell circuit 12 according to the present example embodiment, and is constituted of the two cell transistors without including a cell control transistor.

One side of diffusion layer of the first cell transistor 125 is connected to an intermediate node 113 of the unit element 11. The other diffusion layer of the first cell transistor 125 is connected to one side of diffusion layer of the second cell transistor 127. A gate of the first cell transistor 125 is connected to a second decoding line HDec.

One of the diffusion layers of the second cell transistor 127 is connected to one of the diffusion layers of the first cell transistor 125. The other diffusion layer of the second cell transistor 127 is connected to an intermediate node writing driver 143. In FIG. 3, a connection between the second cell transistor 127 and the intermediate node writing driver 143 is indicated by an arrow. The plurality of second cell transistors 127 included in the crossbar circuit 100 are connected to the common intermediate node writing driver 143. A gate of the second cell transistor 127 is connected to the second decoding line HDec. The gate of the second cell transistor 127 associated with the unit element 11 to be disposed in the same column is connected to the common second decoding line HDec.

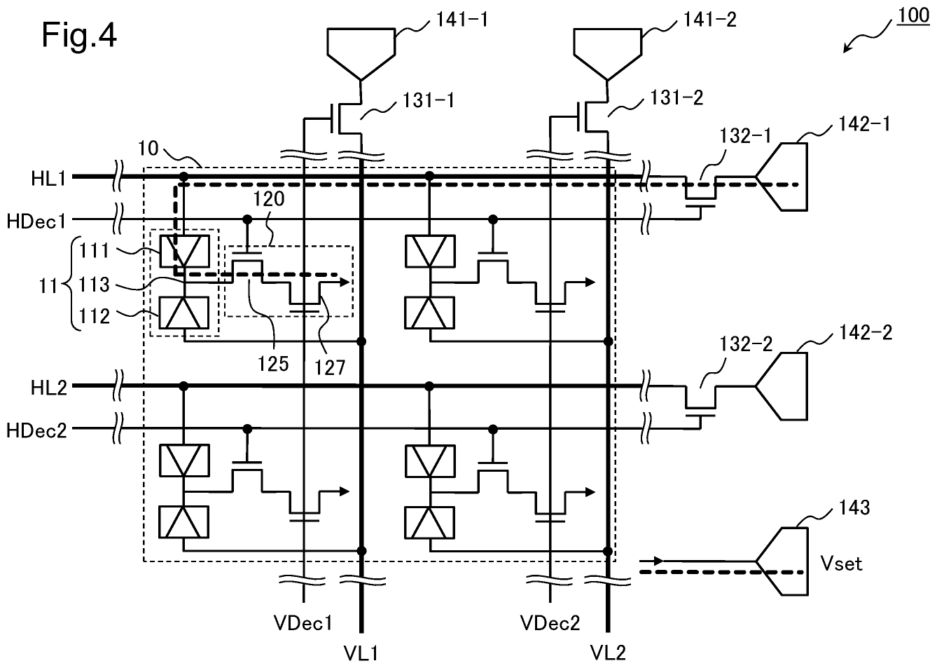

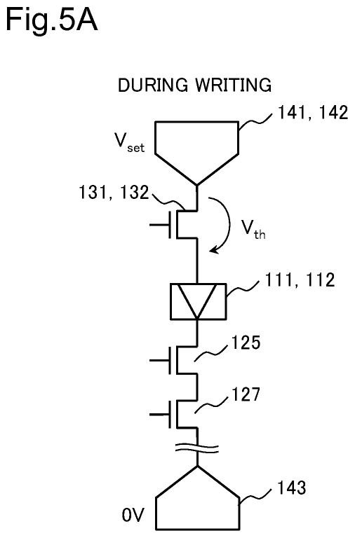

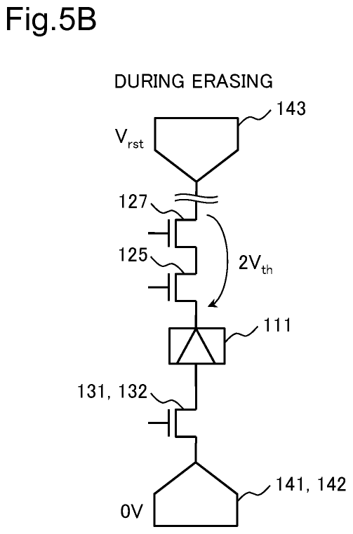

FIG. 4 is a schematic diagram illustrating one example (broken line) of a current path when writing and erasing of the unit element 11 on the upper left is performed in the crossbar circuit 100 according to the related art in FIG. 3. FIGS. 5A and 5B are a schematic diagram illustrating one example of a current path during writing (FIG. 5A) and during erasing (FIG. 5B) related to the unit element 11 to be selected in the crossbar circuit 100 according to the related art. Note that writing refers to a change in a resistance state of a resistance change element from a high resistance state to a low resistance state. Further, erasing refers to a change in a resistance state of a resistance change element from a low resistance state to a high resistance state.

During writing (FIG. 5A), either a first writing driver 141 or a second writing driver 142 is set to a set voltage Vₛₑₜ, and the intermediate node writing driver 143 is set to a ground Gnd (0 volt). At this time, an nMOSFET (the first cell transistor 125 or the second cell transistor 127) in two stages is connected to a Gnd side.

On the other hand, during erasing (FIG. 5B), the intermediate node writing driver 143 is set to a set voltage Vₛₑₜ, and either the first writing driver 141 or the second writing driver 142 is set to a ground Gnd (0 volt). At this time, the nMOSFET (the first cell transistor 125 or the second cell transistor 127) in two stages is connected to a reset voltage Vᵣₛₜ side.

In the crossbar circuit 100 according to the related art, a voltage drop of a threshold voltage Vₜₕ occurs by the nMOSFET in one stage during writing. On the other hand, during erasing, when the nMOSFET in both the two stages operates in a saturation region, a voltage drop of the threshold voltage Vₜₕ×2 occurs at maximum. In other words, during erasing, a voltage of a value acquired by subtracting twice the threshold voltage Vₜₕ from the set voltage Vₛₑₜ is applied to the resistance change element of the crossbar circuit 100 according to the related art. Therefore, in the crossbar circuit 100 according to the related art, a sufficient voltage may be less likely to be applied to the resistance change element constituting the unit element 11 during erasing in which a voltage drop becomes great. Thus, when a gate voltage of the nMOSFET in the two stages is set to be greater than the reset voltage Vᵣₛₜ, a voltage drop by the nMOSFET in the two stages can also be suppressed. However, when the gate voltage of the nMOSFET in the two stages is set to be greater than the reset voltage Vᵣₛₜ, there is a limit in terms of pressure resistance of a transistor, and thus a writing margin with respect to an OFF disturbance decreases. Further, one nMOSFET is operated in a linear region by increasing a gate width, and thus a voltage drop can also be reduced. However, when the gate width is increased, an element size is significantly increased.

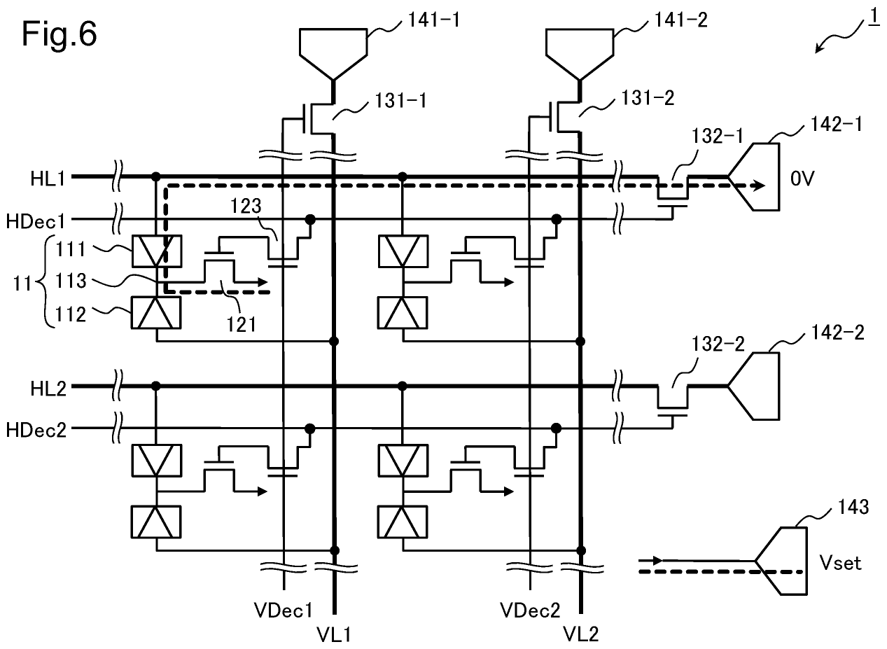

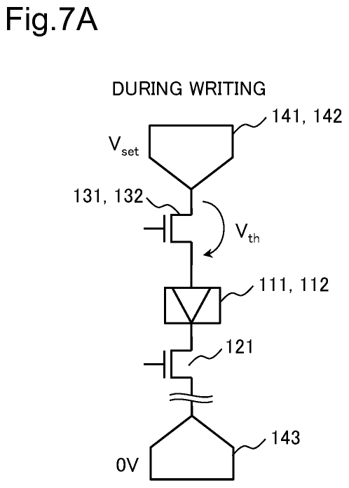

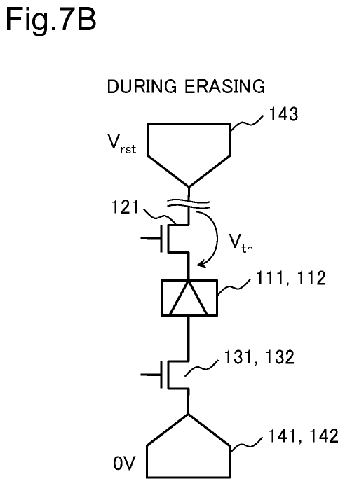

FIG. 6 is a schematic diagram illustrating one example (broken line) of a current path when writing and erasing of the unit element 11 on the upper left is performed in the crossbar circuit 1 according to the present example embodiment in FIG. 1. FIGS. 7A and 7B are a schematic diagram illustrating one example of a current path during writing (FIG. 7A) and during erasing (FIG. 7B) related to the unit element 11 to be selected in the crossbar circuit 1 according to the present example embodiment.

During writing (FIG. 7A), either the first writing driver 141 or the second writing driver 142 is set to a set voltage Vₛₑₜ, and the intermediate node writing driver 143 is set to a ground Gnd (0 volt). At this time, an nMOSFET (the cell transistor 121) in one stage is connected to a ground Gnd side.

On the other hand, during erasing (FIG. 7B), the intermediate node writing driver 143 is set to a reset voltage Vᵣₛₜ, and either the first writing driver 141 or the second writing driver 142 is set to a ground Gnd (0 volt). At this time, the nMOSFET (the cell transistor 121) in one stage is connected to a reset voltage Vᵣₛₜ side.

In the crossbar circuit 1 according to the present example embodiment, a voltage drop of a threshold voltage Vₜₕ occurs by the nMOSFET in one stage during writing, and a voltage drop of the threshold voltage Vₜₕ also occurs by the nMOSFET in one stage during erasing. In other words, an equivalent voltage drop occurs in the resistance change element of the crossbar circuit 1 according to the present example embodiment during both of writing and erasing. Therefore, since a voltage drop is equivalent during writing and erasing in the crossbar circuit 1 according to the present example embodiment, a sufficient voltage is applied to the resistance change element constituting the unit element 11. Thus, a voltage drop of the reset voltage Vᵣₛₜ does not need to be suppressed by increasing a gate voltage of the cell transistor, and a writing margin with respect to an OFF disturbance can be secured while reducing a problem of pressure resistance of a transistor.

As described above, the crossbar circuit according to the present example embodiment includes the cell circuit including the cell transistor to be connected to the intermediate node of the unit element, and the cell control transistor that controls a gate of the cell transistor. In the cell control transistor, a source is connected to the second decoding line, and a gate is connected to the first decoding line. The cell transistor to be connected to the unit element to be selected is brought into a continuity state when both of the first decoding line and the second decoding line to be connected to the cell control transistor associated with the cell transistor are at a selection level. By controlling a polarity of a voltage or a current between the writing driver and the intermediate node writing driver in this state, the unit element to be programmed can be programmed.

The crossbar circuit according to the present example embodiment may set a condition where a combined capacitance of a stray capacitance of wiring connecting the gate of the cell transistor and the cell control transistor and a gate capacitance of the cell transistor, and a fringe capacitance between the diffusion layer and the gate of the cell control transistor are coupled. In this condition, the cell control transistor can be used as a boost circuit. As a result, according to the crossbar circuit of the present example embodiment, a gate voltage of the cell transistor temporarily rises during writing to and erasing from the resistance change element, and a decrease in voltage applied to the resistance change element can be suppressed. For example, when a combined capacitance of a stray capacitance of the wiring connecting the gate of the cell transistor and the cell control transistor and a gate capacitance of the cell transistor is equal to or less than one-tenth of a fringe capacitance between the diffusion layer and the gate of the cell control transistor, the combined capacitance and the fringe capacitance can be easily coupled. For example, a combined capacitance of a stray capacitance of the wiring connecting the gate of the cell transistor and the cell control transistor and a gate capacitance of the cell transistor is more desirably equal to or less than one-fifth of a fringe capacitance between the diffusion layer and the gate of the cell control transistor.

In the crossbar circuit according to the present example embodiment, writing can be performed at once when a writing voltage is applied to the resistance change element during a writing time having a sufficient length. However, in a case where a voltage of the source terminal of the cell control transistor is at the selection level and a voltage of the gate terminal is at the non-selection level, the gate electrode of the cell transistor may be charged due to a subthreshold leak when the writing time is too long, and may be brought into a semi-selection state. Thus, the writing time may be set to be short to an extent that the gate electrode of the cell transistor is not brought into a semi-selection state, and writing may be repeated for a predetermined number of times. When writing is repeated, a gate voltage of the cell transistor can be boosted for every writing, and thus a decrease in voltage applied to the resistance change element can be further suppressed.

Further, in the crossbar circuit according to the present example embodiment, a voltage drop due to the number of transistors to be disposed between the writing driver and the resistance change element is equivalent during writing and erasing. Thus, a set voltage does not need to be increased in order to increase a voltage applied to the resistance change element constituting the unit element during either writing or erasing, and a writing margin with respect to an OFF disturbance can be maintained. Further, since a set voltage does not need to be increased, pressure resistance of a transistor does not need to be increased, and thus a size of the transistor does not also need to be increased.

Further, in the crossbar circuit according to the present example embodiment, a potential of a decoding wire to be connected to the diffusion layer of the cell control transistor is preferably set to 0 volt periodically in order to maintain a gate voltage of the non-selected cell transistor as 0 V. In other words, in the crossbar circuit according to the present example embodiment, it is preferable that a second decoding wire is refreshed for every writing, and the cell transistor that needs to be non-selected maintains a non-continuity state.

Further, in the crossbar circuit according to the present example embodiment, a selection voltage of a selected unit element may be set to be higher than a writing voltage from the writing driver to an extent that does not exceed pressure resistance of an MOSFET. When the selection voltage is set to be higher than the writing voltage from the writing driver to the extent that does not exceed the pressure resistance of the MOSFET, a decrease in the writing voltage to be applied to the resistance change element can be further suppressed.

In other words, the present example embodiment is able to provide a semiconductor device capable of suppressing a decrease in applied voltage to a resistance change element during writing and erasing in the crossbar circuit using the resistance change element.

### Second Example Embodiment

Next, a crossbar circuit according to a second example embodiment of the present invention will be described with reference to the drawing. The crossbar circuit according to the present example embodiment is different from the crossbar circuit according to the first example embodiment in a configuration of a cell circuit. Note that a configuration similar to that of the first example embodiment has the same reference sign as that of the first example embodiment, and detailed description thereof may be omitted.

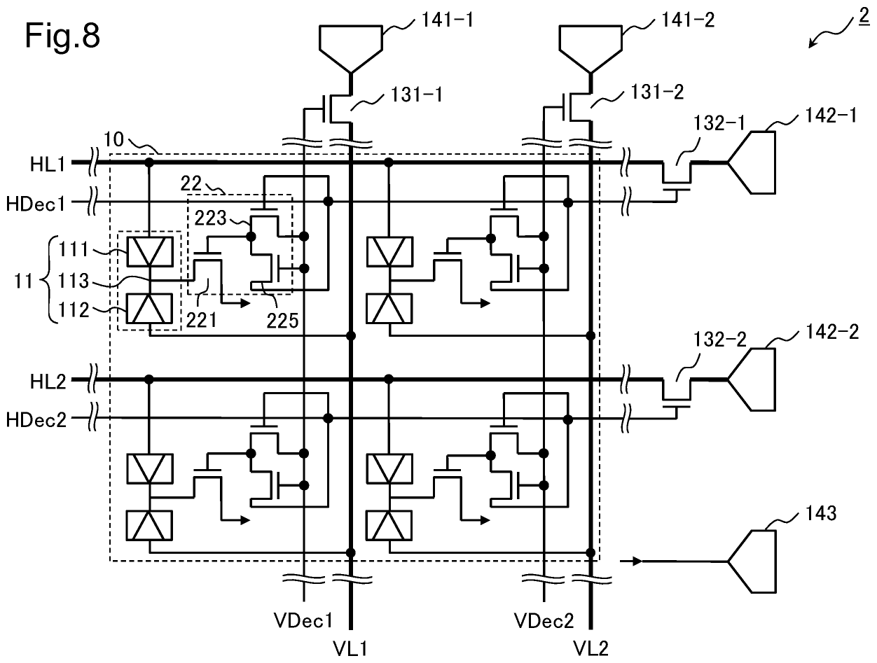

FIG. 8 is a schematic diagram illustrating one example of a configuration of a crossbar circuit 2 according to the present example embodiment. As in FIG. 8, the crossbar circuit 2 includes a wiring network 10, a unit element 11, and a cell circuit 22. The crossbar circuit 2 has a configuration in which the cell circuit 12 of the crossbar circuit 1 according to the first example embodiment is replaced with the cell circuit 22. Hereinafter, since the wiring network 10 and the unit element 11 are similar to those of the first example embodiment except for a connection state with the cell circuit 22, detailed description thereof will be omitted.

The cell circuit 22 is disposed in such a way as to be associated with the unit element 11 to be disposed in a position where a first wire VL and a second wire HL constituting a crossbar intersect each other. The cell circuit 22 includes a cell transistor 221, a first cell control transistor 223, and a second cell control transistor 225.

One side of diffusion layer of the cell transistor 221 is connected to an intermediate node 113 of the unit element 11. The other diffusion layer of the cell transistor 221 is connected to an intermediate node writing driver 143. In FIG. 8, a connection between the cell transistor 221 and the intermediate node writing driver 143 is indicated by an arrow. The intermediate node writing driver 143 is commonly connected to the plurality of cell transistors 221 included in the crossbar circuit 2. A gate of the cell transistor 221 is connected to one side of diffusion layer of the first cell control transistor 223 and the second cell control transistor 225. The intermediate node writing driver 143 is commonly connected to the cell transistors 221 associated with the plurality of unit elements 11 constituting the crossbar circuit 2.

One of the diffusion layers of the first cell control transistor 223 is connected to the gate of the cell transistor 221 and one of the diffusion layers of the second cell control transistor 225. The other diffusion layer of the first cell control transistor 223 is connected to a first decoding line VDec common to the other first cell control transistor 223 that constitutes the same column of the crossbar. A gate of the first cell control transistor 223 is connected to a second decoding line HDec common to the other first cell control transistor 223 that constitutes the same row of the crossbar.

One of the diffusion layers of the second cell control transistor 225 is connected to the gate of the cell transistor 221 and one of the diffusion layers of the first cell control transistor 223. The other diffusion layer of the second cell control transistor 225 is connected to the second decoding line HDec common to the other second cell control transistor 225 that constitutes the same row of the crossbar. A gate of the second cell control transistor 225 is connected to the first decoding line VDec common to the other second cell control transistor 225 that constitutes the same column of the crossbar.

In other words, the other diffusion layer of the first cell control transistor 223 and the gate of the second cell control transistor 225 are connected to the common first decoding line VDec. Further, the gate of the first cell control transistor 223 and the other diffusion layer of the second cell control transistor 225 are connected to the common second decoding line HDec. A continuity state of the first cell control transistor 223 is an ON state when the second decoding line HDec is at a selection level (High), and is an OFF state when the second decoding line HDec is at a non-selection level (Low). A continuity state of the second cell control transistor 225 is an ON state when the first decoding line VDec is at the selection level (High), and is an OFF state when the first decoding line VDec is at the non-selection level (Low).

A continuity state of the cell transistor 221 is switched depending on a continuity state of the first cell control transistor 223 and the second cell control transistor 225. When the first decoding line VDec is at the selection level (High) and the second decoding line HDec is at the selection level (High), the cell transistor 221 is in an ON state. At this time, the intermediate node 113 and the intermediate node writing driver 143 are connected to each other via the cell transistor 221. By controlling a polarity of a voltage or a current between either a first writing driver 141 or a second writing driver 142 and the intermediate node writing driver 143 in this state, the resistance change element included in the unit element 11 to be selected can be programmed.

As described above, the crossbar circuit according to the present example embodiment includes the cell circuit including the cell transistor to be connected to the intermediate node of the unit element, and the two cell control transistors that control a gate of the cell transistor. In one of the two cell control transistors, a diffusion layer is connected to the first decoding line, and a gate is connected to the second decoding signal line. In the other of the two cell control transistors, a diffusion layer is connected to the second decoding line, and a gate is connected to the first decoding signal line. Further, a drain of the two cell control transistors is commonly connected to the gate of the cell transistor.

The cell transistor of the crossbar circuit according to the present example embodiment is electrically continuous when the first decoding signal line and the second decoding signal line are both in a selection state. On the other hand, in the crossbar circuit according to the present example embodiment, when any one of the first decoding line VDec and the second decoding line HDec is at the selection level and the other is at the non-selection level, a gate voltage of the cell transistor remains at 0 volt. In other words, in the crossbar circuit according to the present example embodiment, a gate voltage of the cell transistor included in a selection circuit of a unit element in a non-selection state can be maintained at 0 volt. Thus, in the crossbar circuit according to the present example embodiment, a voltage of a decoding line does not need to be dynamically set to 0 volt by precharging before writing, and thus control is simplified as compared to the first example embodiment.

### Third Example Embodiment

Next, a crossbar circuit according to a third example embodiment of the present invention will be described with reference to the drawing. The crossbar circuit according to the present example embodiment is a superordinate conceptual configuration of the crossbar circuits according to the first and second example embodiments. Note that a configuration similar to that of the first example embodiment has the same reference sign as that of the first example embodiment, and detailed description thereof may be omitted.

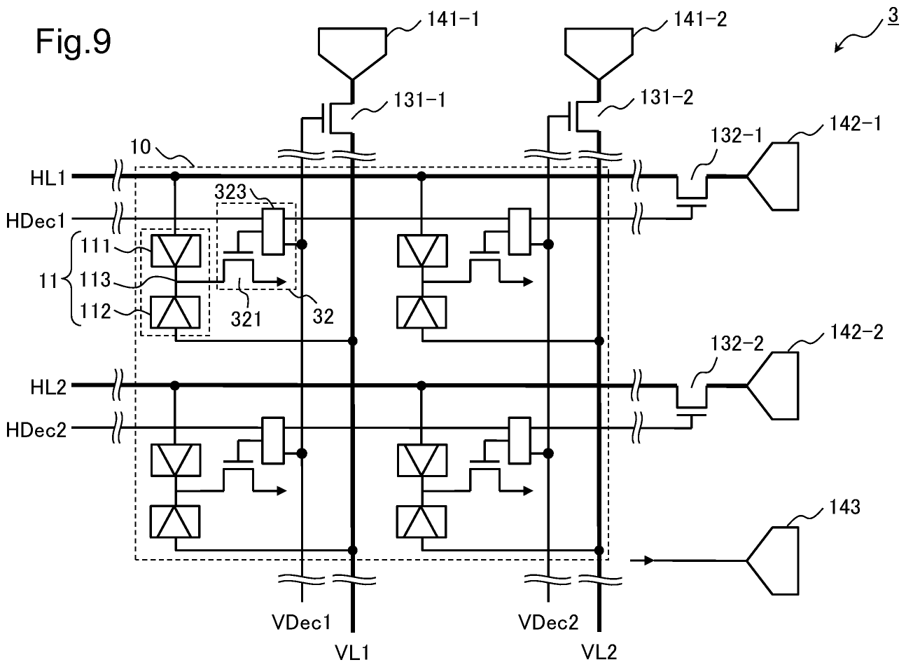

FIG. 9 is a schematic diagram illustrating one example of a configuration of a crossbar circuit 3 according to the present example embodiment. As in FIG. 9, the crossbar circuit 3 includes a wiring network 10, a unit element 11, and a cell circuit 32. The crossbar circuit 2 has a configuration in which the cell circuit 12 of the crossbar circuit 1 according to the first example embodiment is replaced with the cell circuit 32. Hereinafter, since the wiring network 10 and the unit element 11 are similar to those of the first example embodiment, detailed description thereof will be omitted.

The cell circuit 32 is disposed in such a way as to be associated with the unit element 11 to be disposed in a position where a first wire VL and a second wire HL constituting a crossbar intersect each other. The cell circuit 32 includes a cell transistor 321 and a cell control circuit 323.

One side of diffusion layer of the cell transistor 321 is connected to an intermediate node 113 of the unit element 11. The other diffusion layer of the cell transistor 321 is connected to an intermediate node writing driver 143. In FIG. 9, a connection between the cell transistor 321 and the intermediate node writing driver 143 is indicated by an arrow. The intermediate node writing driver 143 is commonly connected to the plurality of cell transistors 321 included in the crossbar circuit 3. A gate of the cell transistor 321 is connected to the cell control circuit 323. The intermediate node writing driver 143 is commonly connected to the cell transistors 321 associated with the plurality of unit elements 11 constituting the crossbar circuit 3.

The cell control circuit 323 is connected to the gate of the cell transistor 321, a first decoding line VDec, and a second decoding line HDec. The cell control circuit 323 to be disposed in the same column of the crossbar is connected to the common first decoding line VDec. The cell control circuit 323 to be disposed in the same row of the crossbar is connected to the common second decoding line HDec. The cell control circuit 323 controls a continuity state of the cell transistor 321 depending on a selection level of the first decoding line VDec and the second decoding line HDec. For example, the cell control circuit 323 can be constituted of the cell control transistor 123 according to the first example embodiment, and the first cell control transistor 223 and the second cell control transistor 225 according to the second example embodiment.

A continuity state of the cell transistor 321 is switched depending on a continuity state of the cell control circuit 323. A continuity state of the cell control circuit 323 is an ON state when the first decoding line VDec and the second decoding line HDec are at a selection level (High). Further, a continuity state of the cell control circuit 323 is an OFF state when either one of the first decoding line VDec and the second decoding line HDec is at a non-selection level (Low).

When the first decoding line VDec is at the selection level (High) and the second decoding line HDec is at the selection level (High), the cell transistor 321 is in an ON state. At this time, the intermediate node 113 and the intermediate node writing driver 143 are connected to each other via the cell transistor 321. By controlling a polarity of a voltage or a current between either a first writing driver 141 or a second writing driver 142 and the intermediate node writing driver 143 in this state, the selected unit element 11 can be programmed.

As described above, the crossbar circuit according to the present example embodiment includes the cell circuit including the cell transistor to be connected to the intermediate node of the unit element, and the cell control circuit that controls a gate of the cell transistor. The cell control circuit is connected to the first decoding line and the second decoding line. The cell transistor to be connected to the unit element to be programmed is brought into a continuity state when both of the first decoding line and the second decoding line to be connected to the cell control transistor associated with the cell transistor are at the selection level. By controlling a polarity of a voltage or a current between the writing driver and the intermediate node writing driver in this state, the unit element to be programmed can be programmed.

In other words, the crossbar circuit according to the present example embodiment is able to provide a semiconductor device capable of suppressing a decrease in applied voltage to a resistance change element during writing and erasing in the crossbar circuit using the resistance change element.

### Fourth Example Embodiment

Next, a crossbar circuit according to a fourth example embodiment of the present invention will be described with reference to the drawing. The crossbar circuit according to the present example embodiment is different from the crossbar circuit according to the first example embodiment in that a control transistor is disposed between a gate of a selection transistor and a decoding line. Note that a configuration similar to that of the first example embodiment has the same reference sign as that of the first example embodiment, and detailed description thereof may be omitted.

FIG. 10 is a schematic diagram illustrating one example of a configuration of a crossbar circuit 4 according to the present example embodiment. As in FIG. 10, the crossbar circuit 4 includes a wiring network 10, a unit element 11, and a cell circuit 12. Hereinafter, since the wiring network 10, the unit element 11, and the cell circuit 12 are similar to those of the first example embodiment, detailed description thereof will be omitted.

The crossbar circuit 4 includes a first selection transistor 131, a second selection transistor 132, a first writing driver 141, a second writing driver 142, a first control transistor 431, and a second control transistor 432. Further, the crossbar circuit 4 may include an intermediate node writing driver 143.

The first control transistor 431 is connected to a first decoding line VDec and a gate of the first selection transistor 131. The second control transistor 432 is connected to a second decoding line HDec and a gate of the second selection transistor 132. A state where a decoding voltage Vcc continues to be always applied to a gate of the first control transistor 431 and the second control transistor 432 during a writing operation to a resistance change element is assumed.

As described above, in the crossbar circuit according to the present example embodiment, the control transistor is disposed between a gate of the selection transistor and the decoding line. The crossbar circuit according to the present example embodiment may set a condition where a combined capacitance of a stray capacitance of wiring connecting the gate of the selection transistor and the control transistor, a gate capacitance of the selection transistor, and a fringe capacitance between the diffusion layer and the gate of the control transistor are coupled. In this condition, the control transistor can be used as a boost circuit.

Further, in the crossbar circuit according to the present example embodiment, a state where a decoding voltage continues to be applied to the gate of the control transistor disposed between the gate of the selection transistor and the decoding line during a writing operation to the resistance change element is assumed. In such a configuration, when a writing voltage is applied from the first or second writing driver, the selection transistor is always in a boosted state. Thus, a gate voltage of the cell transistor temporarily rises during writing to and erasing from the resistance change element, and a decrease in voltage to be applied to the resistance change element can be suppressed. In other words, according to the crossbar circuit of the present example embodiment, a margin with respect to an OFF disturbance can also be maintained in relation to the selection transistor.

### Fifth Example Embodiment

Next, a crossbar circuit according to a fifth example embodiment of the present invention will be described with reference to the drawing. The crossbar circuit according to the present example embodiment is different from the crossbar circuit according to the second example embodiment in that a control transistor is disposed between a gate of a selection transistor and a decoding line. Note that a configuration similar to that of the second example embodiment has the same reference sign as that of the second example embodiment, and detailed description thereof may be omitted.

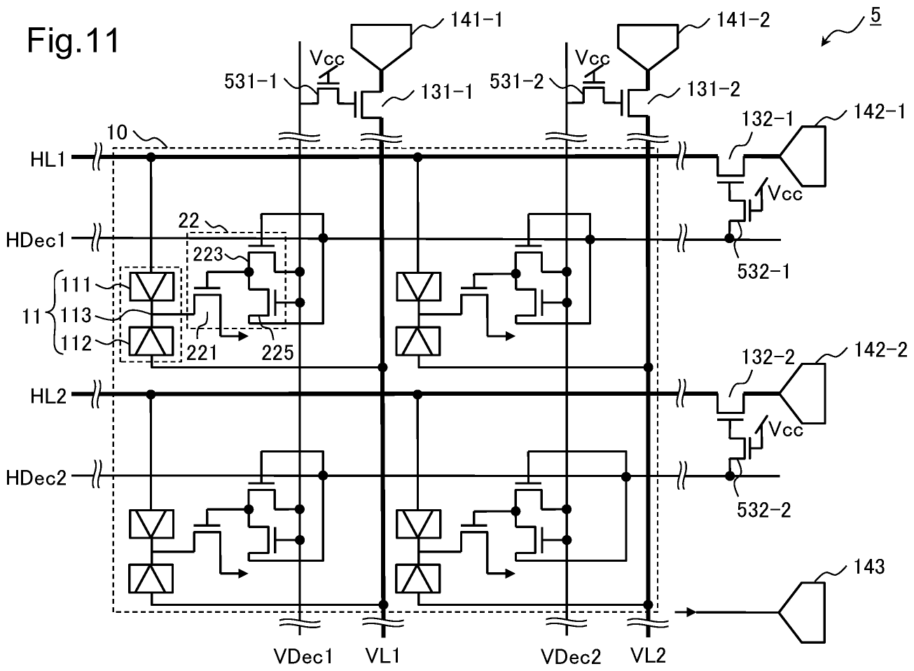

FIG. 11 is a schematic diagram illustrating one example of a configuration of a crossbar circuit 5 according to the present example embodiment. As in FIG. 11, the crossbar circuit 5 includes a wiring network 10, a unit element 11, and a cell circuit 22. Hereinafter, the wiring network 10, the unit element 11, and the cell circuit 22 are similar to those of the second example embodiment, and thus detailed description thereof will be omitted.

The crossbar circuit 5 includes a first selection transistor 131, a second selection transistor 132, a first writing driver 141, a second writing driver 142, a first control transistor 531, and a second control transistor 532. Further, the crossbar circuit 5 may include an intermediate node writing driver 143.

The first control transistor 531 is connected to a first decoding line VDec and a gate of the first selection transistor 131. The second control transistor 532 is connected to a second decoding line HDec and a gate of the second selection transistor 132. A state where a decoding voltage Vcc continues to be applied to a gate of the first control transistor 531 and the second control transistor 532 during a writing operation to a resistance change element is assumed.

As described above, according to the crossbar circuit of the present example embodiment, a margin with respect to an OFF disturbance can also be maintained in relation to the selection transistor in the configuration of the crossbar circuit according to the second example embodiment.

### Sixth Example Embodiment

Next, a semiconductor device according to a sixth example embodiment of the present invention will be described with reference to drawing. The semiconductor device according to the present example embodiment includes any of the crossbar circuits 1 to 5 according to the first to fifth example embodiments and a control device that controls the crossbar circuits 1 to 5.

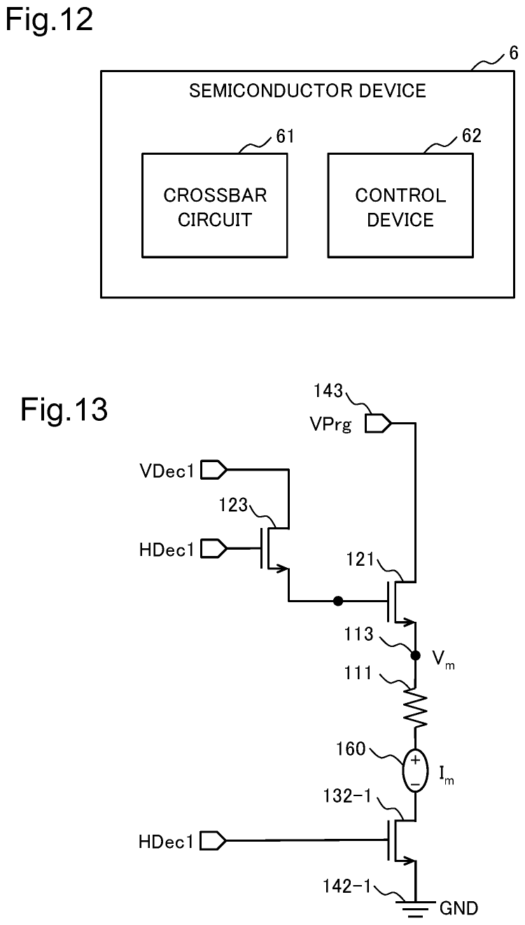

FIG. 12 is a block diagram illustrating one example of a configuration of a semiconductor device 6 according to the present example embodiment. As in FIG. 12, the semiconductor device 6 includes a crossbar circuit 61 and a control device 62.

The crossbar circuit 61 is any of the crossbar circuits 1 to 5 according to the first to fifth example embodiments. When a configuration included in the crossbar circuit 61 is described below, a name and a reference sign of the configuration of the crossbar circuits 1 to 5 are used.

The control device 62 is connected to the crossbar circuit 61. The control device 62 controls the crossbar circuit 61, and performs writing, erasing, and the like of data to and from a desired unit element 11. Note that processing by the control device 62 is not limited to writing and erasing of data to and from the unit element 11.

The control device 62 is connected to a wiring network 10 that constitutes the crossbar circuit 61. Further, the control device 62 is connected to a first writing driver 141, a second writing driver 142, and an intermediate node writing driver 143. Note that the control device 62 may include the first writing driver 141, the second writing driver 142, and the intermediate node writing driver 143.

One example of writing processing to be performed by the control device 62 will be described below.

First, the control device 62 sets all of the first writing drivers 141 and the second writing drivers 142 to 0 volt. Note that, when each of the first writing driver 141 and the second writing driver 142 can be controlled independently, the control device 62 may individually control the first writing driver 141 and the second writing driver 142 associated with the unit element 11 to be selected.

Next, the control device 62 applies a selection voltage to a first decoding line (first control line) and a second decoding line (second control line) connected to the unit element 11 to be selected. At this time, the unit element 11 to be selected is brought into a state of being selected.

Next, the control device 62 applies a predetermined writing voltage from the intermediate node writing driver 143 while the unit element 11 to be selected is selected. For example, the control device 62 can program the selected unit element 11 by controlling a polarity of a voltage or a current between either a first writing driver 141 or a second writing driver 142 and the intermediate node writing driver 143.

The description above is one example of the writing processing to be performed by the control device 62.

In the writing processing described above, the control device 62 may set all of the first writing drivers 141 and the second writing drivers 142 to 0 volt after applying a predetermined writing voltage from the intermediate node writing driver 143. The processing (also referred to as refreshing processing) has an effect when the crossbar circuit 61 is constituted of the crossbar circuit 1 or the crossbar circuit 4.

Further, in the writing processing described above, the control device 62 may set a writing voltage to a greater value than a selection voltage. When a writing voltage is set to be greater than a selection voltage, a decrease in voltage to be applied to a resistance change element can be further suppressed.

Further, the control device 62 may repeat the writing processing mentioned above for a predetermined number of times. By repeating the writing processing, a gate voltage of the cell transistor 121 can be boosted like a pulse in every writing processing.

### (Simulation)

Next, one example of a simulation of the crossbar circuits according to the first and second example embodiments will be described with reference to the drawings. Note that, with regard to the simulation illustrated below, details such as a specific simulation condition and a parameter will be omitted. Further, description is given below by using a configuration name and a reference sign of the crossbar circuit according to each of the example embodiments.

First, simulation results of the crossbar circuit 1 according to the first example embodiment and the crossbar circuit 100 according to the related art are compared.

FIG. 13 is a schematic diagram illustrating a circuit configuration for simulating writing to the unit element 11 on the upper left in the crossbar circuit 1 according to the first example embodiment. In the example in FIG. 13, a case where a current flows through the path indicated by the broken line in FIG. 6 is simulated.

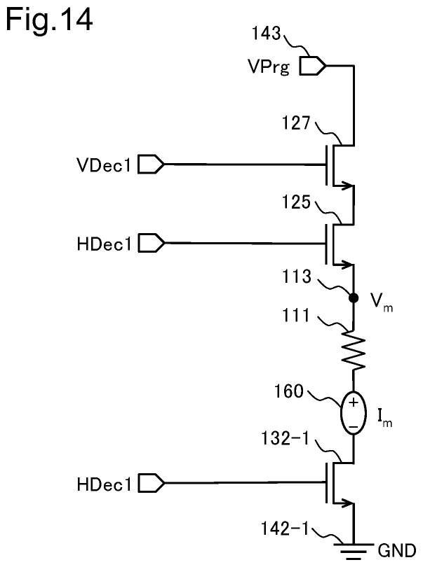

FIG. 14 is a schematic diagram illustrating a circuit configuration for simulating writing to the unit element 11 on the upper left in the crossbar circuit 100 according to the related art. In the example in FIG. 14, a case where a current flows through the path indicated by the broken line in FIG. 4 is simulated.

As in FIGS. 13 and 14, a current measurement element 160 is inserted between the first resistance change element 111 and the second selection transistor 132-1 in the present simulation. Note that the current measurement element 160 is a configuration for performing a simulation. In the example in FIG. 13, the intermediate node writing driver 143 is set to a writing voltage VPrg, and the second writing driver 142-1 is set to a ground GND, and a current Im flowing through the current path and a voltage Vm of the intermediate node 113 are measured.

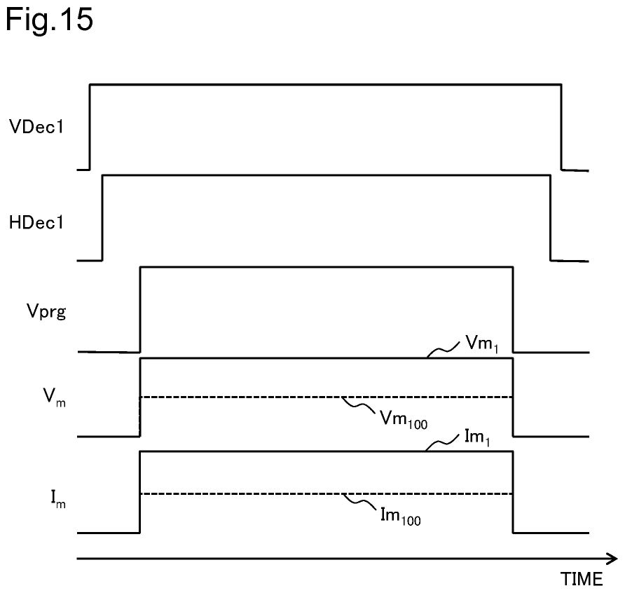

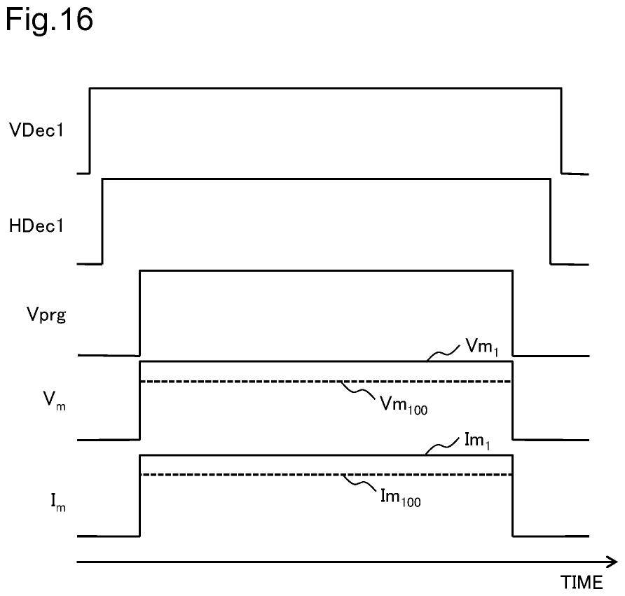

FIG. 15 is a time chart related to a voltage and a current supplied to and measured in the crossbar circuit 1 and the crossbar circuit 100 when the first resistance change element 111 is ON. FIG. 16 is a time chart related to a voltage and a current supplied to the crossbar circuit 1 and the crossbar circuit 100 and a voltage and a current measured in the crossbar circuit 1 and the crossbar circuit 100 when the first resistance change element 111 is OFF.

FIGS. 15 and 16 illustrate a current Im and a voltage Vm measured in the crossbar circuit 1 and the crossbar circuit 100 when a writing voltage VPrg is applied to the first decoding line VDec1, the second decoding line HDec1, and the intermediate node writing driver 143. In FIGS. 15 and 16, a measurement value of the crossbar circuit 1 is indicated by a solid line (current Im₁, voltage Vm₁), and a measurement value of the crossbar circuit 100 is indicated by a broken line (current Im₁₀₀, voltage Vm₁₀₀).

Next, a procedure of the simulation will be described. First, a decoding voltage is applied to the first decoding line VDec1, and a decoding voltage is applied to the second decoding line HDec1. Then, the second writing driver 142-1 is set to 0 volt, and the intermediate node writing driver 143 is set to the writing voltage VPrg. The current Im and the voltage Vm measured at this timing are as illustrated in FIGS. 15 and 16. In other words, in either case where the first resistance change element 111 is ON or OFF, the measurement value (current Im₁, voltage Vm₁) of the crossbar circuit 1 is greater than the measurement value (current Im₁₀₀, voltage Vm₁₀₀) of the crossbar circuit 100.

Next, simulation results of the crossbar circuit 2 according to the second example embodiment and the crossbar circuit 100 according to the related art are compared.

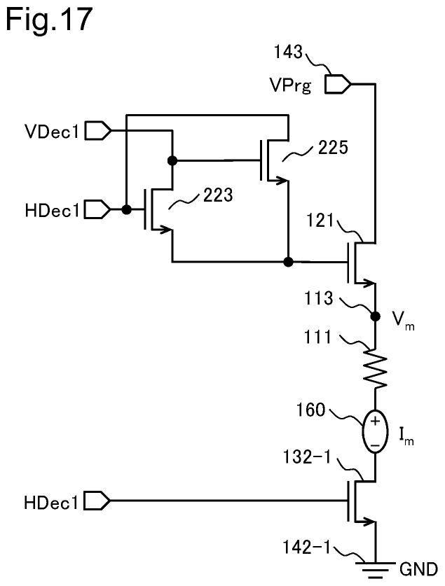

FIG. 17 is a schematic diagram illustrating a circuit configuration for simulating writing to the unit element 11 on the upper left in the crossbar circuit 2 according to the second example embodiment. Also, in the example in FIG. 17, a current path is set between the intermediate node writing driver 143 and the second writing driver 142-1, and a simulation is performed.

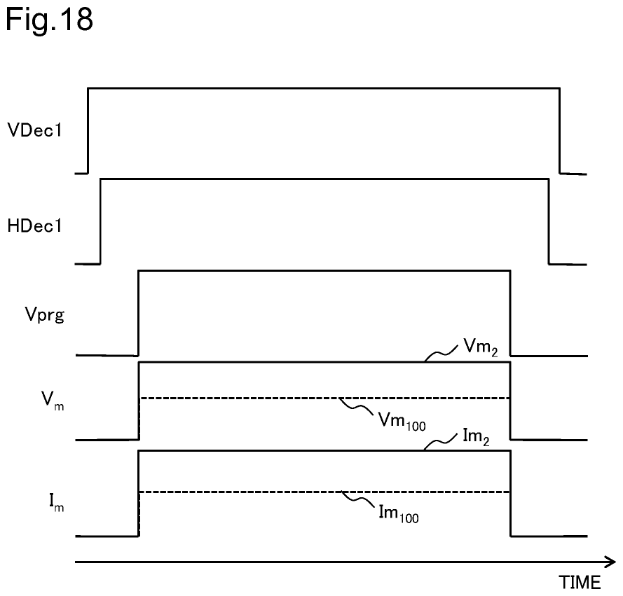

FIG. 18 illustrates a current Im and a voltage Vm measured in the crossbar circuit 2 and the crossbar circuit 100 when a writing voltage VPrg is applied to the first decoding line VDec1, the second decoding line HDec1, and the intermediate node writing driver 143. FIG. 18 illustrates the current Im and the voltage Vm measured in the crossbar circuit 2 and the crossbar circuit 100. In FIG. 18, a measurement value of the crossbar circuit 2 is indicated by a solid line (current Im₂, voltage Vm₂), and a measurement value of the crossbar circuit 100 is indicated by a broken line (current Im₁₀₀, voltage Vm₁₀₀).

Next, a procedure of the simulation will be described. First, a decoding voltage is applied to the first decoding line VDec1, and a decoding voltage is applied to the second decoding line HDec1. Then, the second writing driver 142-1 is set to 0 volt, and the intermediate node writing driver 143 is set to the writing voltage VPrg. The current Im and the voltage Vm measured at this timing are as illustrated in FIG. 18. In other words, in either case where the first resistance change element 111 is ON or OFF, the measurement value (current Im₂, voltage Vm₂) of the crossbar circuit 2 is greater than the measurement value (current Im₁₀₀, voltage Vm₁₀₀) of the crossbar circuit 100.

As described above, according to the crossbar circuit in each of the example embodiments, a current flowing through a cell transistor of a selected unit element is increased, and a voltage drop in the cell transistor is suppressed as compared to the crossbar circuit according to the related art. As a result, according to the crossbar circuit in each of the example embodiments, a great voltage is applied to a resistance change element, and a decrease in the voltage to be applied to the resistance change element can be suppressed as compared to the crossbar circuit according to the related art.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2018-23845, filed on Feb. 14, 2018, the disclosure of which is incorporated herein in its entirety by reference.

### REFERENCE SIGNS LIST

1, 2, 3, 4, 5 Crossbar circuit

6 Semiconductor device

10 Wiring network

11 Unit element

12, 22, 32 Cell circuit

61 Crossbar circuit

62 Control device

111 First resistance change element

112 Second resistance change element

113 Intermediate node

121, 221, 321 Cell transistor

123 Cell control transistor

131 First selection transistor

132 Second selection transistor

141 First writing driver

142 Second writing driver

143 Intermediate node writing driver

223 First cell control transistor

225 Second cell control transistor

323 Cell control circuit

431, 531 First control transistor

432, 532 Second control transistor

What is claimed is:

1. A semiconductor device, comprising:
a plurality of first wires extending in a first direction;
a plurality of second wires extending in a second direction;
a unit element that includes two resistance change elements connected in series, has one end connected to the first wire, and has another end connected to the second wire;
a first control line for controlling a voltage supply to the first wire;
a second control line for controlling a voltage supply to the second wire; and
a cell circuit to be connected to an intermediate node of the two resistance change elements, and also to be connected to the first control line and the second control line, wherein
the cell circuit includes
a cell transistor to be connected to an intermediate node writing driver that supplies a voltage to the intermediate node, and
a cell control circuit that controls a continuity state of the cell transistor.

2. The semiconductor device according to claim 1, wherein
the cell control circuit includes
a cell control transistor,
in the cell transistor,
one side of diffusion layer is connected to the intermediate node, another side of the diffusion layer is connected to the intermediate node writing driver, and a gate is connected to one side of diffusion layer of the cell control transistor, and,
in the cell control transistor,
one side of diffusion layer is connected to one side of diffusion layer of the cell transistor, another side of the diffusion layer is connected to the second control line, and a gate is connected to the first control line.

3. The semiconductor device according to claim 1, wherein
the cell control circuit includes
a first cell control transistor, and
a second cell control transistor,
in the cell transistor,
one side of diffusion layer is connected to the intermediate node, another side of diffusion layer is connected to the intermediate node writing driver, and a gate is connected to one side of diffusion layer of the first cell control transistor and the second cell control transistor,
in the first cell control transistor,
one side of diffusion layer is connected to one side of diffusion layer of the cell transistor, another side of diffusion layer is connected to the first control line, and a gate is connected to the second control line, and,
in the second cell control transistor,
one side of diffusion layer is connected to one side of diffusion layer of the cell transistor, another side of diffusion layer is connected to the second control line, and a gate is connected to the first control line.

4. The semiconductor device according to claim 3, further comprising:
a first selection transistor;
a second selection transistor;
a first writing driver to be connected to one end of the first wire via a diffusion layer of a first selection transistor;
a second writing driver to be connected to one end of the second wire via a diffusion layer of a second selection transistor; and
the intermediate node writing driver to be connected to another side of the diffusion layer of the cell transistor, wherein
the first control line is connected to a gate of the first selection transistor, and
the second control line is connected to a gate of the second selection transistor.

5. The semiconductor device according to claim 4, further comprising:
a first control transistor; and
a second control transistor, wherein
the first control line is connected to a gate of the first selection transistor via the diffusion layer of the first control transistor, and
the second control line is connected to a gate of the second selection transistor via the diffusion layer of the second control transistor.

6. The semiconductor device according to claim 4, further comprising a control device configured to:
set a potential of the first writing driver and the second writing driver to 0 volt,
apply a selection voltage to the first control line and the second control line being connected to the unit element to be selected, and
perform writing processing of performing writing to the unit element selected by controlling a polarity of a voltage or a polarity of a current between either the first writing driver or the second writing driver and the intermediate node writing driver.

7. The semiconductor device according to claim 6, wherein
the control device is configured to set a potential of the second control line to 0 volt after applying a predetermined writing voltage using the intermediate node writing driver.

8. The semiconductor device according to claim 6, wherein
the control device is configured to periodically repeat the writing processing.

9. The semiconductor device according to claim 6, wherein
the control device is configured to set the selection voltage to a value greater than the writing voltage.

10. The semiconductor device according to claim 1, wherein
the intermediate node of the unit element is formed by connecting terminals of an identical polarity of the two resistance change elements of a bipolar type.
